(19) United States
(12) Patent Application Publication
(10) Pub. No.: US 2004/0206963 A1
(43) Pub. Date: Oct. 21, 2004

(54) Method for manufacturing light emitting diode utilizing transparent substrate and metal bonding technology and structure thereof

(75) Inventors: Pan-Tzu Chang, Baoshan Township (TW); Ying-Che Sung, Longtan Township (TW); Wei-Yu Huang, Jhongli City (TW); Chao-Min Chen, Sinpu Township (TW); Wen-Huang Tseng, Jhubei City (TW)

Correspondence Address: Haverstock & Owens LLP, 162 North Wolfe Road, Sunnyvale, CA, 94086, US

(73) Assignee: Arima Optoelectronics Corp.

(21) Appl. No.: 10/824,871

(22) Filed: Apr. 14, 2004

(30) Foreign Application Priority Data
Apr. 16, 2003 (TW) 092108856

(51) Int. Cl. H01L 27/15

(52) U.S. Cl. 257/79

(57) ABSTRACT

A method for manufacturing the light emitting diode utilizing the transparent substrate and the metal bonding technology is provided. The method includes steps of providing a growing substrate, forming a semiconductor structure on the growing substrate, forming a metal bonding layer on the semiconductor structure, bonding a transparent substrate to the semiconductor structure via the metal bonding layer, removing the growing substrate, and forming a first electrode and a second electrode on the semiconductor structure and the transparent substrate respectively.

### FIELD OF THE INVENTION

This invention relates to a method for manufacturing a light emitting diode and a structure thereof, and more particularly to a method for manufacturing a light emitting diode utilizing a transparent substrate and a metal bonding technology and a structure thereof.

### BACKGROUND OF THE INVENTION

The light emitting diode (LED) is a luminescent light emitting component, which emits light through applying a current to the semiconductor materials of III-V group compounds and then transforming the energy into the form of light via the combination of electrons and holes inside the diode. It will not get burned like the incandescent lamp will when being used for a long time. In addition, the light emitting diode further has the advantages of small volume, long lifespan, low driving voltage, rapid response and good vibration-resist property, so that it can meet the requirements of lightness, thinness and miniaturization for many applications and has become a very popular product in daily life.

There are many kinds of light emitting diodes. Through utilizing various semiconductor materials and element structures, the light emitting diodes with different colors such as red, orange, yellow, green, blue and purple as well as the invisible light like infrared and ultraviolet have been designed to be widely used in outdoor signboards, brake lamps, traffic signs, displays, and so on.

Take AlGaInP light emitting diode as an example, AlGaInP is a semiconductor material of four-element compound and suitable for manufacturing red, orange, yellow and yellow-green light emitting diodes with high brightness. The AlGaInP light emitting diode has a high light-emitting efficiency and the lattices thereof are grown and matched on a GaAs substrate. However, since GaAs substrate is a light-absorbing substrate, it will absorb the visible light emitted from AlGaInP. Besides, GaAs substrate has a worse heat conductivity. Therefore, when the LED is driven at a high current level, the light-emitting efficiency thereof is limited.

In order to overcome the drawbacks of the prior art, a new method for manufacturing a light emitting diode and a structure thereof are provided. The particular design of the present invention not only solves the problems described above, but also enhances the light-emitting efficiency. Moreover, the procedures of the method in the present invention are simple and easy to perform. Thus, the present invention has the industrial utility.

### SUMMARY OF THE INVENTION

It is an object of the present invention to provide a method for manufacturing a light emitting diode that utilizes the metal bonding technology for bonding a transparent substrate to replace the light-absorbing GaAs substrate, and enhances the light-emitting efficiency thereof.

In accordance with one aspect of the present invention, the method for manufacturing a light emitting diode includes steps of providing a growing substrate, forming a semiconductor structure on the growing substrate, forming a metal bonding layer on the semiconductor structure, bonding a transparent substrate to the semiconductor structure via the metal bonding layer, removing the growing substrate, and forming a first electrode and a second electrode on the semiconductor structure and the transparent substrate respectively.

Preferably, the growing substrate is a GaAs substrate.

Preferably, the semiconductor structure is a light emitting diode structure.

Preferably, the light emitting diode structure is formed by a four-element material of AlGaInP.

Preferably, the metal bonding layer is one selected from a group consisting of an AuBe, an AuSn, an AuGe, an AuNi, an AuZn, an Au, an AuSi, an Al, an AlSi, an InAu, an InAg, and an Ag thin films.

Preferably, the transparent substrate is one selected from a group consisting of a GaP, a SiC, an AlAs, an AlGaAs and a diamond substrates.

Preferably, the transparent substrate is preferably a GaP substrate.

Preferably, the bonding step is performed at a bonding temperature ranged from 300° C. to 900° C.

Preferably, the bonding step is performed at a bonding pressure ranged from 500 pounds to 5000 pounds.

Preferably, the first electrode and the second electrode are respectively a P-type electrode and an N-type electrode.

Preferably, the first electrode and the second electrode are respectively an N-type electrode and a P-type electrode.

In accordance with another aspect of the present invention, the light emitting diode includes a semiconductor structure for emitting light, a transparent substrate formed on the semiconductor structure via a metal bonding layer between the semiconductor structure and the transparent substrate, and a first electrode and a second electrode respectively formed on the semiconductor structure and the transparent substrate for providing a current to the semiconductor structure.

Preferably, the semiconductor structure is a light emitting diode structure.

Preferably, the light emitting diode structure is formed by a four-element material of AlGaInP.

Preferably, the transparent substrate is one selected from a group consisting of a GaP, a SiC, an AlAs, an AlGaAs and a diamond substrates.

Preferably, the transparent substrate is preferably a GaP substrate.

Preferably, the metal bonding layer is one selected from a group consisting of an AuBe, an AuSn, an AuGe, an AuNi, an AuZn, an Au, an AuSi, an Al, an AlSi, an InAu, an InAg, and an Ag thin films.

Preferably, the metal bonding technology is performed at a bonding temperature ranged from 300° C. to 900° C.

Preferably, the metal bonding technology is performed at a bonding pressure ranged from 500 pounds to 5000 pounds.

Preferably, the first electrode and the second electrode are respectively a P-type electrode and an N-type electrode.

Preferably, the first electrode and the second electrode are respectively an N-type electrode and a P-type electrode.

The above objects and advantages of the present invention will become more readily apparent to those ordinarily skilled in the art after reviewing the following detailed descriptions and accompanying drawings, in which:

### BRIEF DESCRIPTION OF THE DRAWINGS

FIGS. 1(a)˜1(d2) are schematic views showing a manufacturing method of a light emitting diode according to a preferred embodiment of the present invention.

### DETAILED DESCRIPTION OF THE PREFERRED EMBODIMENT

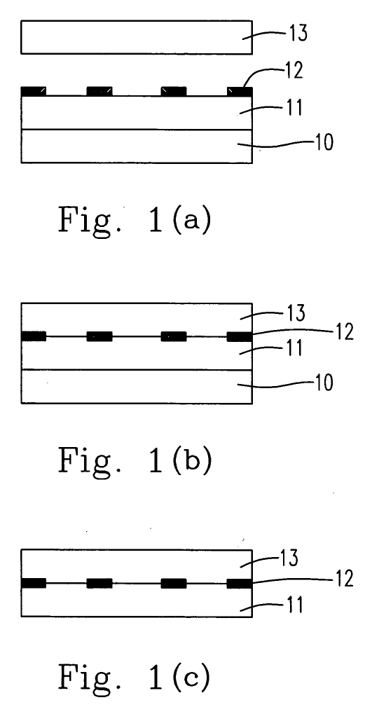

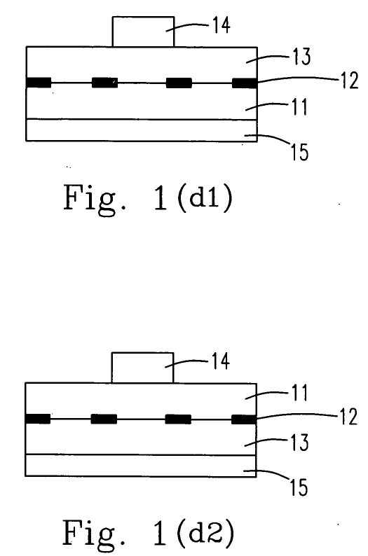

The present invention will now be described more specifically with reference to the following embodiments. Please refer to FIGS. 1(a)˜1(d2), which shows a manufacturing method of a light emitting diode according to a preferred embodiment of the present invention. The procedures of the method are as follows.

At first, a growing substrate 10, such as a GaAs substrate, is provided for crystal growth. Next, a semiconductor structure 11 is grown on the growing substrate 10. The semiconductor structure 11 is a light emitting diode structure composed of multiple layers of multi-element material with different thickness, such as GaAs, GaAsP, AlGaAs and AlGaInP, preferably AlGaInP. Since the crystal growth technology belongs to the prior art, it is not repeatedly described here.

For solving the problem of the prior art that the conventional GaAs substrate is a light-absorbing substrate and thus reduces the light-emitting efficiency, a metal bonding technology is employed in the present invention for bonding a transparent substrate 13 to replace the original GaAs substrate. The metal bonding technology is to plate a metal bonding layer 12 on the semiconductor structure 11. The metal bonding layer 12 can be an AuBe, an AuSn, an AuGe, an AuNi, an AuZn, an Au, an AuSi, an Al, an AlSi, an InAu, an InAg, or an Ag thin film. Subsequently, with conditions that the temperature is controlled within a range from 300° C. to 900° C. (preferably 400° C. to 700° C.) and the pressure is controlled within a range from 500 pounds to 5000 pounds (preferably 1500 pounds to 3500 pounds), the transparent substrate 13 is bonded with and ohmically contacted with the semiconductor structure 11 via the metal bonding layer 12, as shown in FIG. 1(a). In which, the transparent substrate 13 can be a GaP, a SiC, an AlAs, an AlGaAs or a diamond substrate (preferably GaP). The bonded structure is shown in FIG. 1(b).

Then, the growing substrate 10 is removed from the bonded structure by polishing and abrasive slurry burnishing, as shown in FIG. 1(c). Afterward, a P-type electrode 14 and an N-type electrode 15 are respectively formed on the transparent substrate 13 and the semiconductor structure 11 for providing a current to the semiconductor structure 11 so as to make the semiconductor structure 11 emit light in response to the current. Since the GaP transparent substrate 13 employed in the present invention is an electrically conductive substrate, the P-type electrode 14 and the N-type electrode 15 can be respectively disposed on the upper and lower ends of the whole structure, that is, above the transparent substrate 13 and below the semiconductor structure 11, as shown in FIG. 1(d1). Alternatively, the P-type electrode 14 and the N-type electrode 15 can also be respectively disposed above the semiconductor structure 11 and below the transparent substrate 13, as shown in FIG. 1(d2).

In conclusion, the present invention utilizes the metal bonding technology for bonding a GaP transparent substrate to replace the original GaAs substrate that is a light-absorbing substrate, so that the photons emitted downwardly from the light emitting diode will not be absorbed by the GaAs material. In addition, the light emitting diode of the present invention further has advantages of lateral emission with a height of almost 250 mm and high reflective index of the bonding metal, and thus the output power of the light emitting diode can be increased. Moreover, since the heat-dissipating ability of the GaP transparent substrate is several times higher than that of the GaAs substrate, when the light emitting diode is driven at a high current level ranged from several hundred milliamperes to several amperes, the light-emitting efficiency will not be influenced due to the inefficient heat dissipation of the substrate.

Furthermore, compared with the traditional wafer bonding technology utilizing the semiconductor as a bonding layer that has to be bonded at a high temperature ranged from 850° C. to 1000° C., the metal bonding temperature of the present invention is ranged from 300° C. to 900° C., so that the required temperature in the bonding process can be significantly lowered. Therefore, the production cost can be effectively reduced and the yield can be increased.

Since the light emitting diode of the present invention possesses great heat-dissipating efficiency, high transparency of the substrate and mirror reflection of the metal bonding layer, the light-emitting efficiency can be significantly enhanced. In the developing trend for high brightness, high power and large display area, the light emitting diode with the use of transparent substrate and metal bonding technology provided in the present invention will have great industrial values.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method for manufacturing a light emitting diode, comprising steps of:
providing a growing substrate;
forming a semiconductor structure on said growing substrate;
forming a metal bonding layer on said semiconductor structure;
bonding a transparent substrate to said semiconductor structure via said metal bonding layer;
removing said growing substrate; and
forming a first electrode and a second electrode on said semiconductor structure and said transparent substrate respectively.

2. The method as claimed in claim 1, wherein said growing substrate is a GaAs substrate.

3. The method as claimed in claim 1, wherein said semiconductor structure is a light emitting diode structure.

4. The method as claimed in claim 3, wherein said light emitting diode structure is formed by a four-element material of AlGaInP.

5. The method as claimed in claim 1, wherein said metal bonding layer is one selected from a group consisting of an AuBe, an AuSn, an AuGe, an AuNi, and an AuZn thin films.

6. The method as claimed in claim 1, wherein said transparent substrate is one selected from a group consisting of a GaP, a SiC, an AlAs, an AlGaAs and a diamond substrates.

7. The method as claimed in claim 1, wherein said transparent substrate is preferably a GaP substrate.

8. The method as claimed in claim 1, wherein said bonding step is performed at a bonding temperature ranged from 300° C. to 900° C.

9. The method as claimed in claim 1, wherein said bonding step is performed at a bonding pressure ranged from 500 pounds to 5000 pounds.

10. The method as claimed in claim 1, wherein said first electrode and said second electrode are respectively a P-type electrode and an N-type electrode.

11. The method as claimed in claim 1, wherein said first electrode and said second electrode are respectively an N-type electrode and a P-type electrode.

12. A light emitting diode, comprising:
a semiconductor structure for emitting light;
a transparent substrate formed on said semiconductor structure via a metal bonding layer between said semiconductor structure and said transparent substrate; and
a first electrode and a second electrode respectively formed on said semiconductor structure and said transparent substrate for providing a current to said semiconductor structure.

13. The light emitting diode structure as claimed in claim 12, wherein said semiconductor structure is a light emitting diode structure.

14. The light emitting diode structure as claimed in claim 13, wherein said light emitting diode structure is formed by a four-element material of AlGaInP.

15. The light emitting diode structure as claimed in claim 12, wherein said transparent substrate is one selected from a group consisting of a GaP, a SiC, an AlAs, an AlGaAs and a diamond substrates.

16. The light emitting diode structure as claimed in claim 12, wherein said transparent substrate is preferably a GaP substrate.

17. The light emitting diode structure as claimed in claim 12, wherein said metal bonding layer is one selected from a group consisting of an AuBe, an AuSn, an AuGe, an AuNi, and an AuZn thin films.

18. The light emitting diode structure as claimed in claim 12, wherein said metal bonding technology is performed at a bonding temperature ranged from 300° C. to 900° C.

19. The light emitting diode structure as claimed in claim 12, wherein said metal bonding technology is performed at a bonding pressure ranged from 500 pounds to 5000 pounds.

20. The light emitting diode structure as claimed in claim 12, wherein said first electrode and said second electrode are respectively a P-type electrode and an N-type electrode.

21. The light emitting diode structure as claimed in claim 12, wherein said first electrode and said second electrode are respectively an N-type electrode and a P-type electrode.
